(19) United States
(12) Patent Application Publication
(10) Pub. No.: US 2014/0084159 A1
(43) Pub. Date: Mar. 27, 2014

(54) SCANNING ELECTRON MICROSCOPE AND METHOD FOR PREPARING SPECIMEN

(71) Applicants: Kaori Yaeshima, Tokyo (JP); Satoshi Takada, Tokyo (JP); Fumiaki Endo, Tokyo (JP); Tetsuya Niibori, Tokyo (JP)

(72) Inventors: Kaori Yaeshima, Tokyo (JP); Satoshi Takada, Tokyo (JP); Fumiaki Endo, Tokyo (JP); Tetsuya Niibori, Tokyo (JP)

(73) Assignee: HITACHI HIGH-TECHNOLOGIES CORPORATION, Tokyo (JP)

(21) Appl. No.: 14/116,697

(22) PCT Filed: Mar. 14, 2012
(86) PCT No.: PCT/JP2012/001746

§ 371 Date: Nov. 8, 2013

(30) Foreign Application Priority Data
May 17, 2011 (JP) 2011-110003

(51) Int. Cl. H01J 37/28; G01N 23/225

(52) U.S. Cl. CPC H01J 37/28; G01N 23/2251
USPC 250/310

(57) ABSTRACT

In related art, when a location to be analyzed is selected from inspection data, a relatively highly critical defect among entire defects is not selected as a defect to be analyzed. Further, when a mark is placed in a fixed position associated with a defect, the mark affects the defect itself depending on the shape and size of the defect, which is problematic in the following analysis made in an analysis apparatus. Moreover, in the case of a wafer with no pattern, a defect invisible to a SEM cannot be marked.

To select a highly critical defect as a defect to be analyzed, an automatic classification result from a review SEM is used to select a defect to be analyzed. Further, to avoid an effect on a defect itself, a mark is placed in a position associated with the defect with the distance from the defect to the marking position changed on a defect basis. To this end, the shape and size of a defect is recognized based on ADR or ADC, and a mark is placed in a position set apart from the defect by a distance in consideration of a range to be affected by the mark. Further, in the case of a defect that is not observable with a SEM, a mark is placed by using an observation result from an optical microscope.

### TECHNICAL FIELD

The present invention relates to a scanning electron microscope that irradiates a specimen with an electron beam to allow specimen observation and a method for preparing the specimen.

### BACKGROUND ART

As a semiconductor device is increasingly miniaturized and complicated, defects occur in steps of manufacturing the semiconductor device in a variety of ways and in a complicated manner, and the situation increases importance of failure analysis technologies. Further, as the number of defects increases, there are increasing demands not only for an increase in inspection speed but also for defect review for extraction of catastrophic defects.

In failure analysis, the position of a defect on a semiconductor wafer is first detected by using an optical or electronic visual inspection apparatus. Since defects detected by a visual inspection apparatus are usually contaminated with a lot of noise and contain non-critical defects, a defect review apparatus is used to capture a high-resolution image of a portion including the position of each of the defects acquired by the visual inspection apparatus, and the resultant image is used to classify the defect. The defect classification process allows discrimination of critical defects that should undergo failure analysis. In recent years, a defect review apparatus has a function of automatically classifying captured defect images based on taught data, and the function is called ADC (automatic defect classification).

The failure analysis is performed based, for example, on high-resolution observation using a scanning electron microscope (SEM) or a transmission electron microscope (TEM) or element analysis using energy dispersive X-ray spectrometry (EDS) or electron energy-loss spectroscopy (EELS). To perform failure analysis using a transmission electron microscope, a silicon wafer used to manufacture a semiconductor device needs to be divided into chips or columnar samples due to constraints on the specimen size, and a laser apparatus and a focused ion beam (FIB) apparatus are used in the wafer division and the sample preparation.

In the wafer division or the sample preparation using a focused ion beam described above, a mark of some kind is required to cut a target defect off a wafer. In the wafer division, a mark large enough to be visible to an operator is required, and in the sample preparation using a focused ion beam, a mark large enough to be checked in a SIM (scanning ion microscopy) image displayed on an FIB apparatus is required.

As an example of a technology for placing such a mark, JP-A-2000-241319 (PTL 1) discloses an FIB apparatus including an optical defect detector. In the apparatus, a focused ion beam is used to place a mark in a position in the vicinity of an optically detected defect, and the specimen is irradiated with the focused ion beam with respect to the mark to form a TEM sample.

### CITATION LIST

### Patent Literature

PTL 1: JP-A-2000-241319

### SUMMARY OF INVENTION

### Technical Problem

Defects detected by a visual inspection apparatus do not include many critical defects required to undergo failure analysis. All defects detected by a visual inspection apparatus or a defect review apparatus are therefore not always marking target defects. JP-A-2000-241319 discloses an FIB apparatus including an optical defect detector but does not offer an idea that detected defects undergo classification of some kind and marking is performed in accordance with classification results. Further, selection of defects from inspection data resulting from visual inspection based on random sampling will never allow reliable selection of highly critical defects that should undergo failure analysis.

Failure analysis is performed by using an FIB apparatus or a TEM, but identification of the position of a defect is performed by using an apparatus different from an apparatus for failure analysis, such as a visual inspection apparatus or a defect review apparatus, as described above. To perform failure analysis, it is therefore necessary to transfer information on the position of a defect from a defect position identification apparatus to a failure analysis apparatus and identify the position of the defect in the failure analysis apparatus (alignment of field of view).

However, there is a case where the shape of a defect greatly deviates from that in design information due to defective pattern formation, or there is a case where a detected defect is, for example, foreign matter, which is not included in design information. Further, a defect on a specimen having no pattern, such as a bare wafer before pattern formation, a defect under a surface film on a silicon wafer, or any other similar defect is in some cases difficult to locate by using a charged particle beam apparatus that is not originally designed for defect detection, such as an FIB apparatus and a TEM. To perform failure analysis on such a defect, there is no choice but to rely on manual or visual alignment of the field of view because it is difficult to perform automatic alignment of the field of view. To perform manual alignment, it is impossible to perform failure analysis without a mark of some kind representing the position of a defect.

### Solution to Problem

The present invention, in which an automatic defect classification function of a defect review apparatus has a function of classifying an imaged defect as a defect that should undergo failure analysis or not, achieves an object of “reliable selection of a marking target defect” described above. In this case, a marking method may be a beam-based marking using an electron beam or any other charged particle beam or mechanical marking based on impression.

Further, the defect review apparatus including an impression marking unit that places an impression mark allows identification of the position of a defect that is difficult to detect in an image acquired by an analysis apparatus. Since impression is a mark placement method for forming a physical indentation on a specimen, it is expected that wafer division essential in an analysis process can be more efficiently performed because an impression mark is more visible than a mark produced by a marking method using an electron beam.

### Advantageous Effects of Invention

Since the present invention allows a critical defect to be analyzed in a later stage to be selected in accordance with a predetermined strategy, a cause of the defect can be found in an early stage, and the yield can hence be improved.

Further, changing the distance from a defect to a mark in accordance with the shape of the defect allows failure-free analysis. Moreover, a defect that is not observable with a SEM can be analyzed, whereby the quality of a bare wafer and hence the yield can be improved.

### BRIEF DESCRIPTION OF DRAWINGS

FIG. 1 shows the overall configuration of the present embodiment.

FIG. 2A shows the interior of a specimen chamber according to the present embodiment (at the time of review).

FIG. 2B shows the interior of the specimen chamber according to the present embodiment (at the time of impression marking).

FIG. 3 is an example of an analysis flowchart according to the present embodiment.

FIG. 4 shows an example of a marking method according to the present embodiment.

FIG. 5 shows exemplary images of defects characteristic to a bare wafer and captured with a dark field optical microscope.

FIG. 6A shows a first example of an inappropriate impression mark.

FIG. 6B shows a second example of an inappropriate impression mark.

FIG. 6C shows an idea for improving the first example of an inappropriate impression mark.

FIG. 6D shows an idea for improving the second example of an inappropriate impression mark.

FIG. 7 shows an example of a screen displayed on a defect review apparatus according to the present embodiment.

### DESCRIPTION OF EMBODIMENTS

### First Embodiment

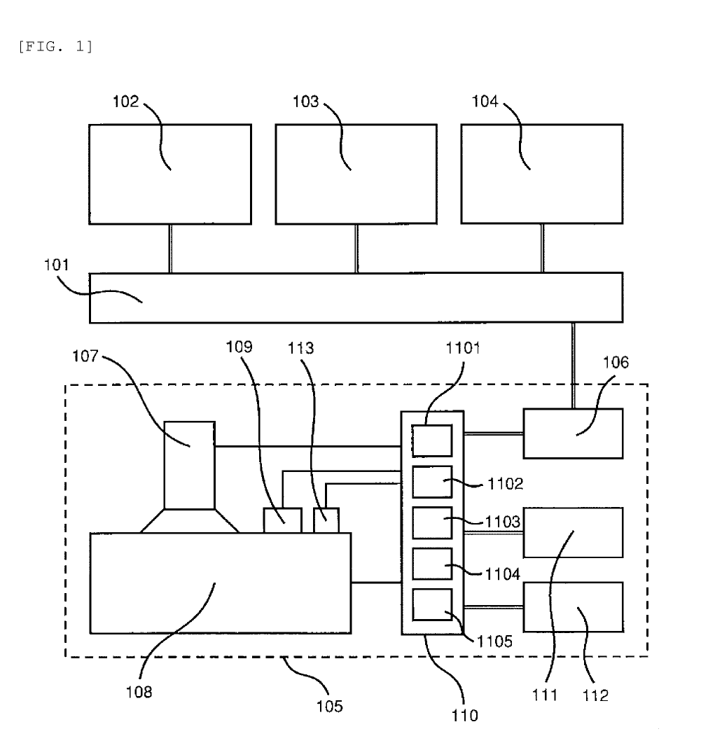

FIG. 1 shows the overall configuration of a defect review apparatus and the configuration of a defect detection system including the defect review apparatus. A defect review apparatus 105 includes a scanning electron microscope column (electronic, optical column) 107, a specimen chamber 108, an impression marking unit 109, an optical microscope 113, a controller 110, an ADR (automatic defect review) unit 111, an ADC (automatic defect classification) unit 112, and a communication computer 106, and the defect review apparatus 105 is connected to a YMS (yield management system) 101 via a network. The YMS 101 is also connected to a bright-field optical visual inspection apparatus 102, a dark-field optical visual inspection apparatus 103, and an electron beam visual inspection apparatus 104 via a network.

Each of the inspection apparatus described above, after inspection is completed, transmits inspection data to the YMS 101 and then to the defect review apparatus 105. The defect review apparatus 105 uses the inspection data to perform ADR and ADC and returns ADR and ADC results to the YMS 101 via the communication computer 106.

The defect review apparatus will next be described in detail. The scanning electron microscope column 107 has a function of irradiating an object under inspection placed in the specimen chamber with a primary electron beam, detecting resultant secondary electrons or reflected electrons, and outputting a detection signal. A specimen stage (not shown) is accommodated in the specimen chamber 108 and moves the object under inspection in accordance with a control signal from the controller 110 in such a way that a target position on the object under inspection to be irradiated with the primary electron beam or a target position where the impression marking unit 109 places an impression mark comes under the scanning electron microscope column 107 or the impression marking unit 109. A scanning electron microscope image captured by the scanning electron microscope column 107 is used not only to identify the position of a defect but also to set a marking position.

The optical microscope 113 is disposed on the top of the specimen chamber 108 and capable of capturing an optical microscopic image of a defect. The field of view of the optical microscope 113 is moved by the specimen stage in the same manner as the field of view of the scanning electron microscope column 107 is moved, and the resultant optical microscopic image is used to identify the position of a defect invisible to the scanning electron microscope and to set a marking position.

Each component of the scanning electron microscope, which is part of the defect review apparatus, is controlled by the controller 110, and the ADR unit 111, the ADC unit 112, and the communication computer 106 are connected to a rear stage of the controller 110. The ADR unit 111 controls a control sequence of the automatic defect review, and the ADC unit 112 automatically classifies defect images captured in the ADR process. The controller 110 includes an electronic, optical column control unit 1101, an impression marking unit control unit 1102, an optical microscopic control unit 1103, a marking target defect extraction unit 1104, a stage control unit 1105, and other control units for controlling the action of the components of the scanning electron microscope. The communication computer 106 also serves as a console for managing the defect review apparatus and includes a monitor that displays a GUI (graphical user's interface) that allows an operator to set conditions under which the defect review is performed or set inspection recipes.

Each of the control units described above is achieved by software or hardware implemented in the controller 110. The controller 110 therefore accommodates a memory that stores a program that provides the function of each of the control units and a processor that executes the program. The controller 110 alternatively includes a plurality of microcomputers corresponding to the functions of the control units.

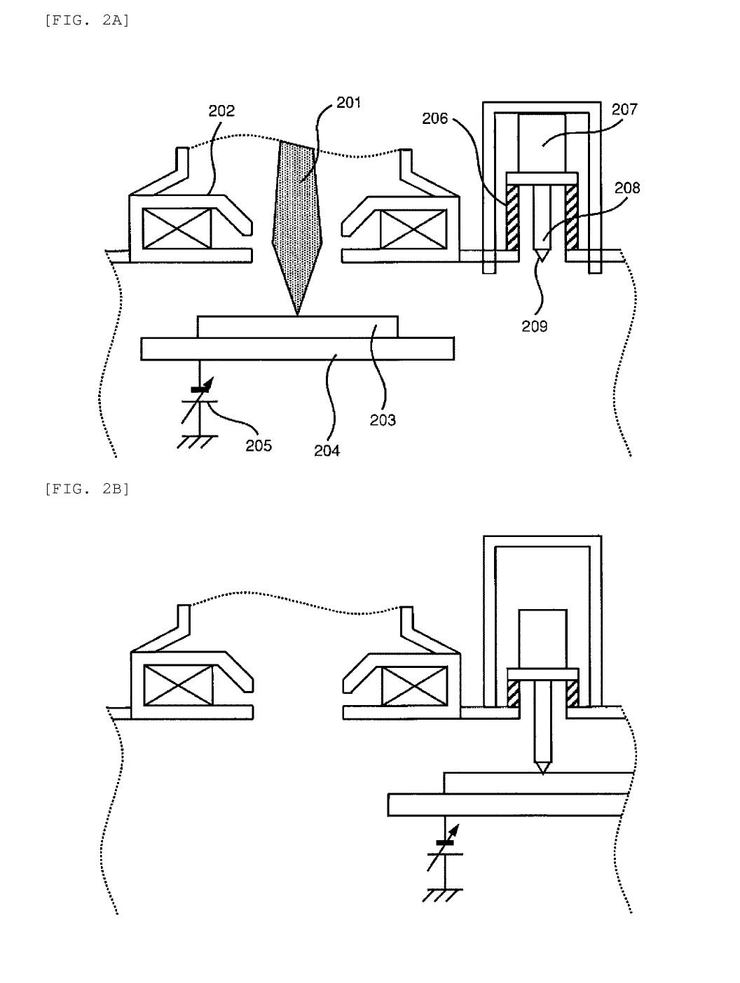

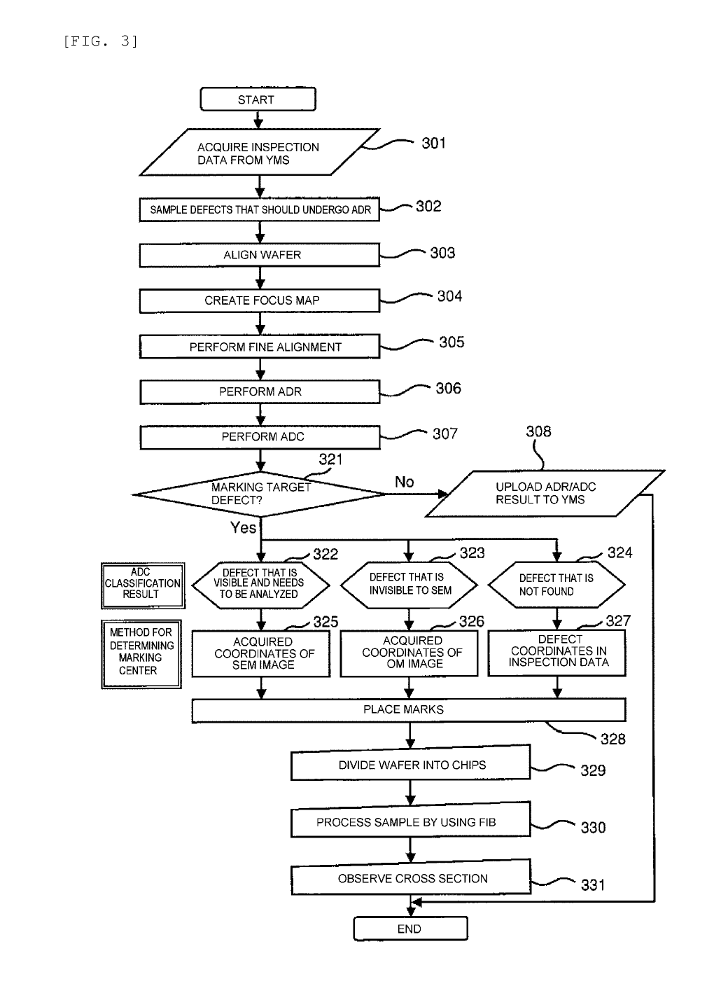

The impression marking unit according to the present embodiment will next be described in detail with reference to FIGS. 2A and 2B. FIG. 2A is a diagrammatic view showing the interior of the specimen chamber and the action of the impression marking unit at the time of defect review. In the specimen chamber 108, an electron beam 201 is focused by an objective lens 202, and a wafer 203 is irradiated with the electron beam 201. The wafer 203 is placed on a stage 204 and moved to an arbitrary position by the stage control unit 1105. Depending on the condition under which a scanning electron microscopic image is acquired, the specimen 203 is imaged with the primary electron beam decelerated immediately before the specimen 203 in some cases. In such cases, a retarding unit 205 applies a retarding voltage to the specimen 203.

At the time of review, the stage 204 successively moves each defect to an inspection position, and the defect is irradiated with the electron beam 201 focused by the objective lens 202 for SEM image acquisition. The defect detection unit 111 detects the defect based on the thus acquired SEM image, and then the defect classification unit classifies the defect. The communication computer 106 uploads the original SEM image, the defect detection result, and the defect classification result to the YMS 101 via the network.

FIG. 2B shows the interior of the specimen chamber at the time of impression marking. To perform the impression marking, the stage control unit 1105 uses the position of a marking target defect that is determined by the marking target defect extraction unit 1104 to control the stage 204 and moves the wafer 203 in such a way that a marking target position thereon comes under the impression marking unit 109.

Upon completion of the movement, in the impression marking unit 109 having a vacuum bellows 206, a vertical drive mechanism 207 lowers an indenter 209 attached to the tip of a shaft 208 and causes the indenter 209 to press the specimen to form an impression mark on the specimen. The action of the impression marking unit is controlled by the impression marking unit control unit 1102.

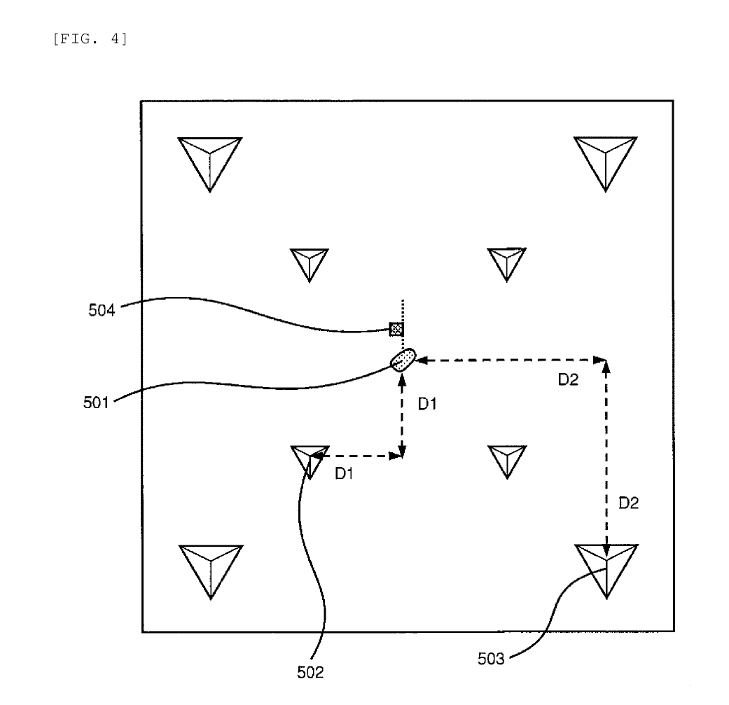

The action of the defect review apparatus according to the present embodiment will next be described with reference to FIG. 3.

First, in step 301, inspection data is read from the YMS. In step 302, sampling is so performed that defects that should undergo ADR are extracted from the defects contained in the inspection data. The purpose of the sampling is to narrow defects that should undergo ADR from a large number of defects so that effective ADR can be performed within a limited period, and the narrowing operation is performed, for example, by extracting and eliminating cluster defects and randomly extracting defects from the defects containing no cluster defects. In step 303, a wafer is aligned, and hence the wafer is roughly positioned. In step 304, a focus map is created, and a focus distribution in each in-plane area of the wafer is corrected in accordance with the focus map, whereby autofocusing is achieved in a short period. In step 305, the wafer undergoes fine alignment in the SEM. The fine alignment is performed by using a specific pattern on a mask-shot basis in a photolithography process when the wafer has a pattern thereon, whereas the fine alignment is performed by receiving light from a defect under an optical microscope, particularly, a dark field microscope using laser light or any other suitable apparatus to accurately detect the position of the defect when the wafer has no pattern thereon. In step 306, ADR is so performed that an accurate position of the defect is detected and an SEM image containing the defect located at the center of the image is acquired. In step 307, ADC is performed based on the SEM image to produce a classification result.

After the ADC in step 307, the ADC unit 112 transfers the classification result to the marking target defect extraction unit 1104 in the controller 110, and the marking target defect extraction unit 1104 judges whether the classified defect is a marking target defect and extracts the marking target defect (step 321). When the classification result contains no marking target defect, the ADR/ADC result is uploaded to the YMS 101 via the communication computer 106 (step 308), and the action of the defect review apparatus is terminated.

In step 321, when the defect is judged to be a marking target defect, the marking target defect extraction unit 1104 carries out the step of classifying the ADC classification result as one of the following three categories. It is noted that no mark can be placed in a defect position because the mark affects the defect itself and hence accurate failure analysis cannot be made. In view of the fact described above, in the marking operation, an appropriate marking center is set, and a mark is placed in a position set apart from the marking center with the distance from the marking center to the mark changed on a defect basis. It is therefore necessary to determine the position of the marking center on a defect basis as well as the shape and size of the defect and other information on the ADC classification result.

(1) The defect is observable with the SEM (step 322)
(2) The defect is not observable with the SEM but is observable with the optical microscope (step 323)
(3) The defect is not observable with the SEM nor the optical microscope (step 324)

After the ADC classification result is classified as one of the above three categories, the step of determining the marking center in accordance with the category is carried out.

In the case of (1), the center of the field of view of a SEM image is determined to be the position of the marking center (step 325). In the case of (2), the center of the field of view of an optical microscope image is determined to be the position of the marking center (step 326). The optical microscope image acquired in step 305 is used as an optical microscope image used to determine the marking center. In the case of (3), the marking center is determined by using original defect coordinates in the inspection data received from an external inspection apparatus, such as the bright-field optical visual inspection apparatus, the dark-field optical visual inspection apparatus, or the electron beam visual inspection apparatus (step 327).

After the marking center is determined, the marking target defect extraction unit 1104 determines marking coordinates based on the determined marking center and transmits the marking coordinates to the impression marking unit control unit 1102. The impression marking unit control unit 1102 controls the impression marking unit 109 to actually place a mark in a position having the coordinates determined in step 328.

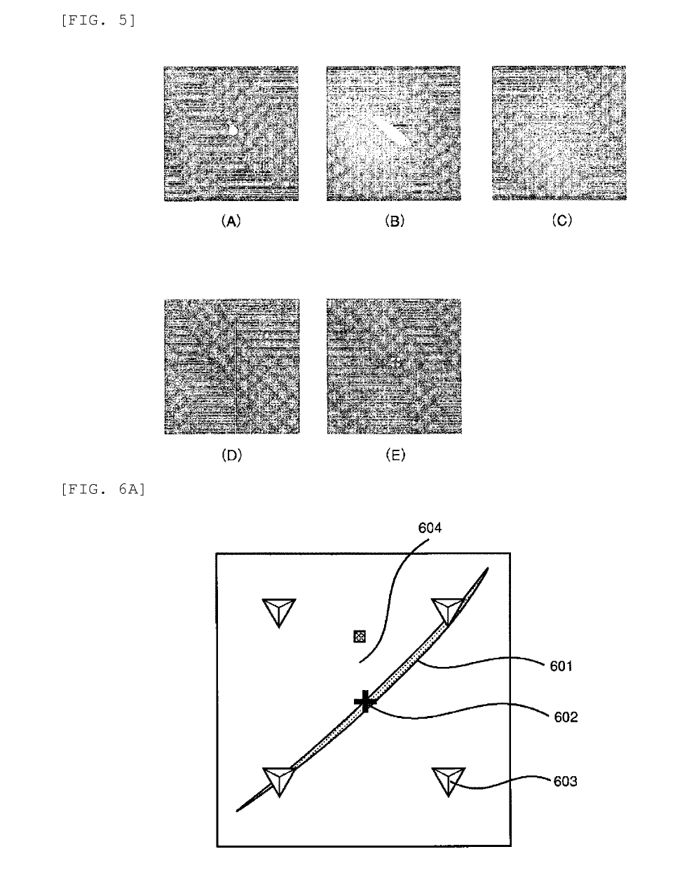

A description will next be made of a method for determining a marking position according to the present embodiment with reference FIG. 4. FIG. 4 is a diagrammatic view showing a marking position in the present embodiment. The marking center is set substantially at the center of a defect 501, and first impression marks 502 are placed in positions set apart from the marking center by a distance D1 in XY directions. The distance D1 is determined in consideration of the precision of the coordinates of the impression marks and effects of the impression marks on the portions therearound. The first impression marks 502 are placed at the four vertices of a square surrounding the defect, and an operator of the failure analysis apparatus may search for the defect within the square. A mark indicating a cross section producing position or an EB mark 504 is further placed in a position in the vicinity of the defect. An EB mark is formed by irradiating the specimen with the primary electron beam 201 for several minutes to induce EB contamination. An EB mark is formed with high positional precision because it can be formed in a size according to the magnification of the SEM and can hence indicate an accurate cross section producing position even in an image captured with an imaging device provided in the analysis apparatus.

When a wafer is divided, the dividing operation is readily performed in some cases with the aid of other marks outside the first impression marks. In such cases, a distance D2 is so determined that it is smaller than the size that fits in a specimen holder of the analysis apparatus by a margin including coordinate inaccuracy, and second impression marks 503 are placed at the four vertices of a square having sides set apart from the marking center by the distance D2 in the XY directions. The marks are so placed that the size thereof is as large as possible for good visibility, which allows the wafer to be divided into chips with very high efficiency. As described above, using a plurality of marks for different purposes can increase efficiency of a variety of processes, such as the wafer division and the searching for the beam irradiation position performed by the analysis apparatus.

After all marking target defects have been marked, the marking operation is terminated and the specimen 203 is removed from the defect review apparatus.

The impression marking or EB marking described above can be manually performed by the operator of the apparatus or can be automatically performed by the apparatus. To automatically perform the two types of marking, the distances D1 and D2 and the distance between the EB marking position and the marking center described above are tabulated in relation to a defect characteristic value, such as the defect type or the defect size, and stored in the memory in the controller 110. The stage control unit 1105 then reads the table in the memory and moves the stage in such a way that a marking target position comes under the impression marking unit or the electronic, optical column.

After the specimen 203 is removed, an analysis target is manually determined. A method for selecting an analysis target, for example, includes selecting a few main defects that frequently occur among entire defects, a few rare defects specific to a wafer under inspection, and a few defects of a variety of other kinds and grasping the overall situation of the defects.

The wafer is then divided into chips having a size accommodated in a holder of the analysis apparatus (step 329). In step 330, each of the chips is placed in the FIB apparatus, where the defect positions are searched for and a material of some kind is deposited or otherwise placed on the surface of the chip or the surface is otherwise protected as required. Thereafter, a cross section that the operator desires to observe is produced by using the FIB, and the resultant structure is further made thinner and then removed as a specimen. In step 331, a TEM or a high-resolution SEM is used to observe the cross section of the resultant thin piece.

In a method of related art, even when a specimen has a defect that should undergo failure analysis, the specimen is provided with no mark for defect search but transferred into an FIB apparatus in many cases. In this case, it takes time to search for the defect in the FIB apparatus. In the case of a bare wafer, which has no pattern, for example, in particular, it takes a very long time to search for a minute defect. According to the present embodiment, since the defect review apparatus can place an impression mark directly in a position associated with a critical defect, the cross section producing position can be searched for in the analysis apparatus in a very efficient manner as compared with the searching in related art.

As described above, since the present embodiment allows a critical defect to be analyzed in a later stage to be selected in accordance with a predetermined strategy, a cause of the defect can be found in an early stage, and the yield can hence be improved. Further, a defect that is not observable with a SEM can be analyzed, whereby the quality of a bare wafer and hence the yield can be improved.

### Second Embodiment

The first embodiment has been described with reference to an example of the configuration of the defect review apparatus that determines marking coordinates with respect to a marking center. In the present embodiment, a description will be made of the configuration of a defect review apparatus having a function of determining marking coordinates by using another method. The overall configuration of the apparatus is the same as that shown in FIG. 1, and the same components and functions of the apparatus will therefore not be described and FIG. 1 will be referred to as appropriate below.

Since marking the center of a defect affects the defect itself, no mark can be placed in the position of the defect, as described above. Determining marking positions set apart from a marking center in a fixed manner (distances D1 and D2, for example) and placing marks in the determined positions, however, may cause any of the marks to be placed in the position of a defect depending on the shape and size of the defect in some cases.

To show such cases described above, FIG. 5 shows exemplary images of defects characteristic to a bare wafer and captured with a dark field optical microscope. FIG. 5(A) shows foreign matter. FIG. 5(B) shows a PID (polishing induced defect). FIG. 5(C) shows a shallow scratch. FIG. 5(D) shows a slip. FIG. 5(E) shows a stacking fault. In these cases, the defects shown in FIGS. 5(A) to 5(E) are categorized as follows in many cases: The defects shown in FIGS. 5(A) and 5(B) can be observed with a SEM; the defects shown in FIGS. 5(C) and 5(D) cannot be observed with a SEM but can be observed with an optical microscope; and the defect shown in FIG. 5(E) cannot be observed with a SEM nor with an optical microscope. The categorization described above is, however, not always true due to effects of the size and other factors. As described above, the shape and size of a defect detected by a defect review apparatus vary on a defect basis.

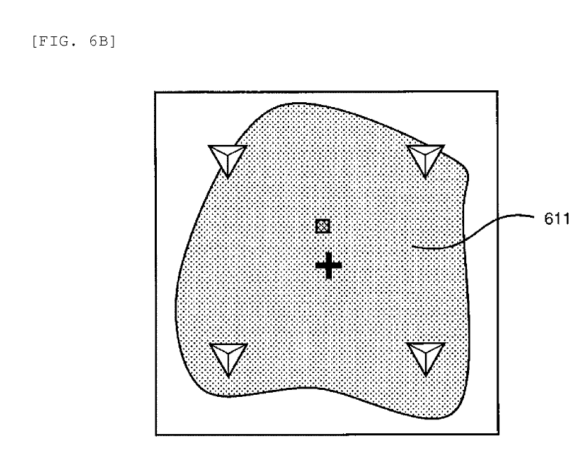

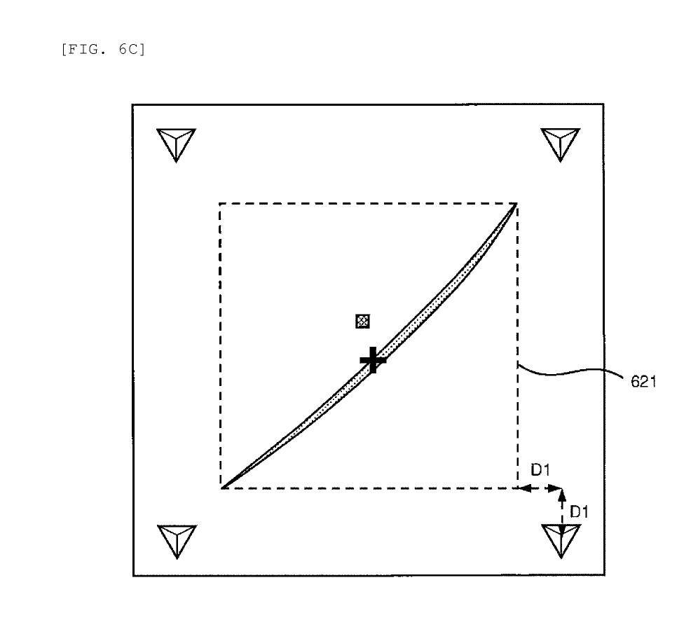

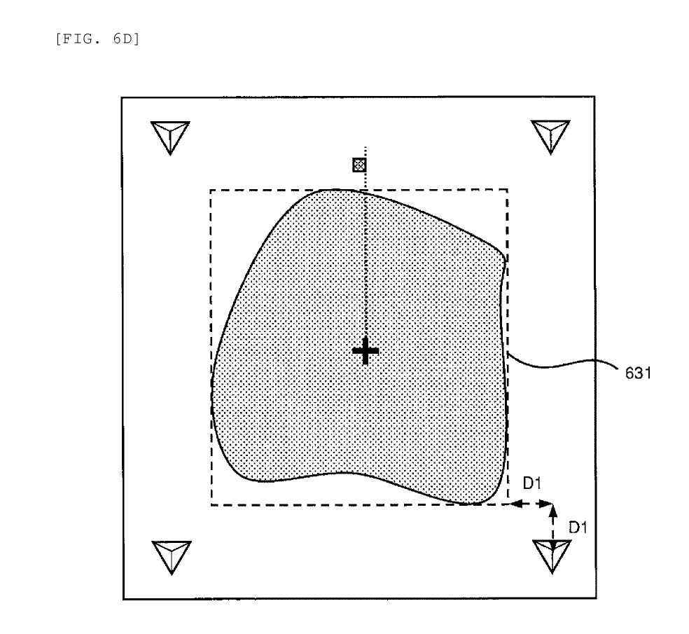

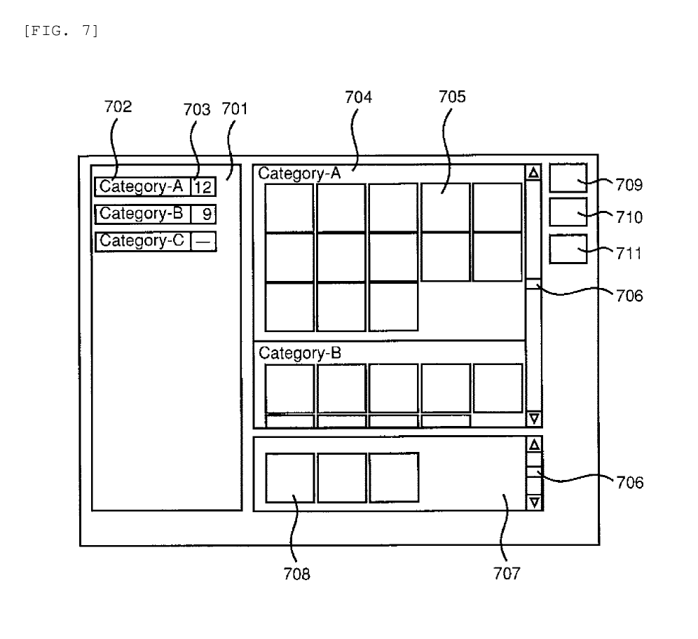

A description will next be made of examples of a defect on which an inappropriate impression mark is placed with reference to FIGS. 6A and 6B. FIG. 6A shows a first example of an inappropriate impression mark. The defect in this case is a linear defect 601, the length of which is longer than an originally expected length. An EB mark 604 is not particularly problematic, but impression marks 603 set apart from the center 602 of the defect by a distance D1 undesirably overlap with the defect. FIG. 6B shows a second example of an inappropriate impression mark. The defect in this case is a huge defect 611, and the impression marks 603 set apart from the center 602 of the defect by the distance D1 are entirely on the defect. Further, the EB mark 604 is also undesirably on the defect and hence prevents the operator from recognizing the position thereof.

FIG. 6C shows an idea for improving the marking example shown in FIG. 6A. When a defect judged to be a marking target defect is a linear defect, the marking target defect extraction unit 1104 in the controller determines a smallest square 621, which circumscribes the defect. Computation required for the determination can be performed by using the coordinates of each end point of the defect image. The marking target defect extraction unit 1104 further sets first impression marking positions having the coordinates of the vertices of the determined smallest square 621 to which the distance D1 is added. The position of the EB marking is set in accordance with the basic method described above.

FIG. 6D shows an idea for improving the marking example shown in FIG. 6B. When a defect judged to be a marking target defect is a huge defect, the marking target defect extraction unit 1104 determines a smallest square 631, which circumscribes the defect, and sets first impression marking positions having the coordinates of the vertices of the smallest square 621 to which the distance D1 is added, as in FIG. 6C. Further, an EB marking is also set in a position shifted outward from a side of the smallest square 621 by a distance set for the EB marking.

To implement the function described above in the apparatus, the computation procedure of the calculation of marking positions according to the type of defect as well as the distances D1, D2 and the distance for the EB marking described above are tabulated and stored in the memory in the controller 110. The marking target defect extraction unit 1104 then refers to the table in the memory and sets marking target positions according to a defect. The information on the set marking target positions is referred to by the impression marking unit and the stage control unit, and impression marks are placed in the predetermined target positions.

FIG. 7 shows an example of the configuration of a GUI used in the first or second embodiment. The GUI shown in FIG. 7 is displayed on the monitor associated with the communication computer 106. Reference character 701 denotes an ADC result display section. Reference character 702 denotes an ADC classification result. Reference character 703 denotes the number of classified defects. Reference character 704 denotes an ADC result image display section. Reference character 705 denotes an ADC result image. Reference character 706 denotes a slide bar. Reference character 707 denotes a marking target image display section. Reference character 708 denotes a marking target image. Reference character 709 denotes a marking target selection button. Reference character 710 denotes a marking target deselection button. Reference character 711 denotes a marking execution button.

Referring to the ADC classification results 702 and the numbers of classified defects 703 displayed in the ADC result display section 701, the operator moves the ADC result images 705 displayed in the ADC result image display section 704 with the slide bar 706 and determines a marking target image. The determination is made by selecting an ADC result image and pressing the marking target selection button 709. The determination can alternatively be made by dragging and dropping an ADC result image 705 into the marking target image display section 707. The selected ADC image 705 is added to the marking target image display section 707 and displayed therein as a marking target image 708. The marking target image 708 having been added can be removed from the marking target image display section 707 by selecting it and pressing the marking target deselection button 710. After all marking target images 708 are selected, the marking operation is initiated by pressing the marking execution button 711.

As described above, the present embodiment allows the distance to a mark to be changed in accordance with the shape of a defect, whereby the occurrence of failure in processes before analysis is reduced.

### REFERENCE SIGNS LIST

101 YMS
102 Bright-field optical visual inspection apparatus
103 Dark-field optical visual inspection apparatus
104 Electron beam visual inspection apparatus
105 Defect review apparatus
106 Communication computer
107 Scanning electron microscope column
108 Specimen chamber
109 Impression marking unit
110 Controller
111 ADR unit
112 ADC unit
113 Optical microscope (OM)
201 Electron beam
202 Objective lens
203 Specimen (wafer)
204 Stage
205 Retarding unit
206 Vacuum bellows
207 Vertical drive mechanism
208 Shaft
209 Indenter
501 Defect
502 Impression mark (small)
503 Impression mark (large)
504, 604 EB mark
601 Linear defect
602 Center of defect
603 Impression mark
611 Huge defect
621 Smallest square circumscribing linear defect
631 Smallest square circumscribing huge defect
701 ADC result display section
702 ADC classification result
703 Number of classified defects
704 ADC result image display section
705 ADC result image
706 Slide bar
707 Marking target image display section
708 Marking target image
709 Marking target selection button
710 Marking target deselection button
711 Marking execution button
1101 Electronic, optical column control unit
1102 Impression marking unit control unit
1103 Optical microscope control unit
1104 Marking target defect extraction unit
1105 Stage control unit

1. A defect review apparatus having a function of acquiring a scanning electron microscope image of a known defect position on a specimen and allowing observation of the defect position, the apparatus comprising:
an electronic, optical column that irradiates the defect position with a primary electron beam and outputs resultant secondary electrons or reflected electrons as a detection signal;
a specimen stage on which the specimen is placed, the specimen stage moving the specimen to change the position on the specimen where the specimen is irradiated with the primary electron beam; and
a defect classification unit that uses a defect image produced from the detection signal to classify the defect on the specimen as a marking target defect or a non-marking target defect,
wherein the marking target defect undergoes electron beam marking using the primary electron beam in such a way that a portion around the defect is marked.

2. A defect review apparatus having a function of acquiring a scanning electron microscope image of a known defect position on a specimen and allowing observation of the defect position, wherein the apparatus comprises:
an electronic, optical column that irradiates the defect position with a primary electron beam and outputs resultant secondary electrons or reflected electrons as a detection signal;
a specimen stage on which the specimen is placed, the specimen stage moving the specimen to change a field of imaged view of the electronic, optical column; and
an impression marking unit that places an impression mark in a plurality of positions around the defect.

3. The defect review apparatus according to claim 2,
wherein the defect review apparatus further comprises a defect classification unit that uses a defect image produced from the detection signal to classify the defect on the specimen as a marking target defect or a non-marking target defect.

4. The defect review apparatus according to claim 3,
wherein the defect review apparatus further comprises a marking position computation unit that determines the position associated with the marking target defect where each of the impression marks is placed.

5. The defect review apparatus according to claim 3,
wherein the marking position computation unit changes the position where each of the impression marks is placed in accordance with the size of the defect.

6. The defect review apparatus according to claim 3,
wherein the defect review apparatus further comprises a stage control unit that controls the specimen stage in such a way that the positions where the impression marks are placed coincide with the marking positions determined by the impression marking unit.

7. The defect review apparatus according to claim 2,
wherein electron beam marking is performed as well as the impression marking.

8. The defect review apparatus according to claim 7,
wherein the position where the electron beam marking is performed is closer to the defect than the position where each of the impression marks is placed.

9. The defect review apparatus according to claim 3,
wherein the defect review apparatus further comprises an optical microscope unit that captures an optical microscope image of the defect, and
the defect classification unit classifies the defect as one of the following categories:
1) a defect observable as a scanning electron microscope image;
2) a defect observable as an optical microscope image but not observable as a scanning electron microscope image; and
3) a defect not observable as a scanning electron microscope image nor as an optical microscope image.

10. The defect review apparatus according to claim 9,
wherein the center of the positions where the impression marks are placed is changed in accordance with the classification result, 1), 2), or 3).

11. The defect review apparatus according to claim 10,
wherein the centering method is based on contour extraction.

12. The defect review apparatus according to claim 1,
wherein the defect review apparatus further comprises a management computer including a monitor that displays a condition setting screen for setting a condition according to which the electron beam marking or the impression marking is performed, and
a button for specifying whether or not marking is performed is displayed on the condition setting screen.

13. The defect review apparatus according to claim 2,
wherein a defect that is not foreign matter on a bare wafer is extracted as a marking target defect.
